(19) United States
(12) Patent Application Publication
(10) Pub. No.: US 2007/0131939 A1
(43) Pub. Date: Jun. 14, 2007

(54) Semiconductor laser and method for manufacturing the same

(76) Inventor: Shinichi Kohda, Kyoto-shi (JP)

Correspondence Address: RABIN & Berdo, PC, 1101 14TH STREET, NW, SUITE 500, WASHINGTON, DC, 20005, US

(21) Appl. No.: 10/578,477

(22) PCT Filed: Nov. 12, 2004
(86) PCT No.: PCT/JP04/16872

§ 371 Date: May 8, 2006

(30) Foreign Application Priority Data
Nov. 12, 2003 (JP) 2003-382954

(51) Int. Cl. H01L 33/00; H01L 31/12; H01L 27/15; H01L 29/26

(52) U.S. Cl. 257/79

(57) ABSTRACT

A semiconductor lamination portion (9) including an active layer (4) is formed on a substrate (1). The semiconductor lamination portion is made of, for example, a nitride material having a cleavage plane not parallel to a cleavage plane of the substrate (1) and has a resonance cavity end faces (6) from which a laser beam is emitted. And a metal layer portion (5) is provided between the substrate and the active layer in a vicinity of the resonance cavity end faces. As a result, even if a crack is caused between the substrate and the semiconductor lamination portion, an extension of the crack stops at the metal layer portion, thereby the crack does not reach to the active layer at the resonance cavity end faces, and the cleavage plane free from any crack can be obtained at the resonance cavity end faces. Therefore, as an absorption loss at the resonance cavity end faces is reduced, the semiconductor laser which is driven with low operating current and has high reliability can be obtained.

### FIELD OF THE INVENTION

The present invention relates to a semiconductor laser which has a semiconductor lamination portion being made of a material having a cleavage plane not parallel to a cleavage plane of a substrate and to a method for manufacturing the same.

### BACKGROUND OF THE INVENTION

Accompanied with a recent tendency of elevating an optical recording density, shortening a wavelength of a semiconductor laser for use in a read-out operation or the like is expected and developing a nitride semiconductor laser for use in a high density DVD or the like has been promoted energetically. In the nitride semiconductor laser, as shown in FIG. 6, a semiconductor lamination portion 59 including an n-type semiconductor layer 52, an active layer 54 and a p-type semiconductor layer 53 is formed on a sapphire substrate 51. A p-electrode 58 is formed on a topmost surface of the p-type semiconductor layer 53 which is etched in a stripe shape for constricting a current region and, on the other hand, an n-electrode 57 is formed on a partially exposed surface of the n-type semiconductor layer 52. And resonance cavity end faces (which means end faces of a resonance cavity) are formed in a direction perpendicular to a lamination surface of the semiconductor lamination portion 59 (cf. PATENT DOCUMENT 1).

PATENT DOCUMENT 1: Japanese Patent application Laid-Open No. HEI08-097502 (FIG. 3)

### DISCLOSURE OF THE INVENTION

### Problem to be Solved

Generally, a semiconductor laser emits an amplified light mainly from one of resonance cavity end faces, after amplifying a light generated by a current injection by repeating reflections at the resonance cavity end faces. Therefore, it is necessary to reduce absorption of the laser beam at the resonance cavity end faces, in order to lower a threshold current and an operating current of the semiconductor laser, to the utmost. In order to achieve the above described object, a cleavage plane of a crystal material used for a semiconductor lamination portion is generally employed for the resonance cavity end faces. However, in case of a nitride semiconductor laser, there exists a problem that a laser oscillation cannot be obtained even if the resonance cavity end faces are formed parallel to the cleavage plane of the nitride material used for the semiconductor lamination portion, or that the operation current becomes high even if the laser oscillation is realized.

Exactly, a sapphire substrate or the like on which the nitride material is suitably grown is generally used for a substrate of the nitride semiconductor laser. However, depending on the substrates, there is a case that the cleavage plane of the substrate is not parallel to that of the nitride material composing the semiconductor lamination portion or that the substrate has no cleavage plane in itself. Therefore, when the resonance cavity end faces are attempted to be formed by cleaving the semiconductor lamination portion, many cracks are caused in a cross section of the substrate which has the cleavage plane not parallel to that of the semiconductor lamination portion. And the cracks caused in the substrate extend to the cleavage plane of the semiconductor lamination portion resulting in a rough cleavage plane of the semiconductor lamination portion. Thus, as far as the semiconductor lamination portion and the substrate are contacted to each other, the extension of the cracks cannot be avoided and a satisfactory cleavage plane cannot be obtained at the semiconductor lamination portion. Thereby, as an optical loss at the resonance cavity end faces increases, and a laser oscillation cannot be realized due to an insufficient amplification or the operation current value increases.

On the other hand, as another method for forming the resonance cavity end faces, a method of forming an artificial resonance cavity end faces by using a dry etching process has been attempted instead of forming the resonance cavity end faces by using the cleavage plane. However, even though the dry etching process is applied, a level of its surface finishing is limited and a surface condition like that by the cleavage plane cannot be obtained. Furthermore, as a plasma treatment is applied in the dry etching process, the resonance cavity end faces suffer from damages by treating plasma and lead to a deterioration in a reliability.

An object of the present invention is to solve the above described problems and to provide a semiconductor laser which is driven with low operating current and has high reliability by reducing the absorption loss at the resonance cavity end faces. Additionally, another object of the present invention is to provide a method for manufacturing the above described semiconductor laser which is driven with low operating current and has high reliability.

### MEANS FOR SOLVING THE PROBLEM

A semiconductor laser according to the present invention includes: a substrate; a semiconductor lamination portion including an active layer laminated on the substrate, the semiconductor lamination portion being made of a material having a cleavage plane not parallel to a cleavage plane of the substrate; and a metal layer portion provided between the substrate and the active layer in a vicinity of a resonance cavity end face (end face of a resonance cavity).

Here, the material having the cleavage plane not parallel to that of the substrate means all materials except materials having the cleavage plane parallel to that of the substrate and in the case that the substrate has no cleavage plane it means any material of the semiconductor lamination portion which has the cleavage plane. And the vicinity of the resonance cavity end face means a region which includes at least one of the resonance cavity end faces emitting laser beam therefrom and includes a case that the metal layer portion is formed beyond the above described region.

And it is preferable that the metal layer portion includes an element which is contained in the semiconductor lamination portion. By this composition, the active layer is prevented from a deterioration of a crystal structure and a complication of a manufacturing process can be avoided.

A method for manufacturing a semiconductor laser according to the present invention is characterized in a process which has the steps of: forming a semiconductor lamination portion including an active layer on a substrate, the semiconductor lamination portion being made of the material having the cleavage plane not parallel to the cleavage plane of the substrate; forming a metal layer portion by melting a part of the semiconductor lamination portion; and forming resonance cavity end faces by cleaving the semiconductor lamination portion at the metal layer portion.

More specifically, the above described method is characterized in the process of forming the metal layer portion which is performed by irradiating a laser beam from a back surface of the substrate opposite to a surface laminated with the semiconductor lamination portion, and thereby melting a part of the semiconductor lamination portion. As the semiconductor lamination portion can be melted easily by this method, the complication of the manufacturing process can be avoided.

### EFFECT OF THE INVENTION

By the method according to the present invention, the substrate and the active layer are not contacted each other only through the semiconductor layer in a vicinity of the resonance cavity end faces because a metal layer portion is provided between the substrate and the active layer. As a result, a crack which is caused on the substrate in the step of forming the resonance cavity end faces along the cleavage plane of the semiconductor lamination portion is absorbed at the metal layer portion and cannot extend to a side of the semiconductor lamination portion and any crack does not occur in the active layer. Then the resonance cavity end faces of the active layer can be mirror-finished. And, a more mirror-like surface than the artificially finished surface of the resonance cavity end faces by a method of dry etching or the like can be obtained. Therefore, as an absorption loss at the resonance cavity end faces is reduced, the semiconductor laser which is driven with low operating current and has high reliability can be obtained.

And, by the method according to the present invention, as the resonance cavity end faces are formed by cleaving at the position of the metal layer portion, a crack which is caused on the substrate is absorbed at the metal layer portion and cannot extend to a side of the semiconductor lamination portion and any crack does not occur in the semiconductor lamination portion. Then the resonance cavity end faces of the semiconductor lamination portion can be mirror-finished. Furthermore, as a part of the semiconductor lamination portion is melted after forming the semiconductor lamination portion, the semiconductor lamination portion being previously laminated does not receive any influence, and the semiconductor lamination portion of fine quality can be obtained.

### BRIEF DESCRIPTION OF THE DRAWINGS

FIG. 1 is a perspective view explaining an embodiment of a semiconductor laser according to the present invention.

FIG. 2 is a cross-sectional view showing a plane perpendicular to resonance cavity end faces of the semiconductor laser.

FIGS. 3A to 3C are views showing one surface of the resonance cavity end faces of the semiconductor laser shown in FIG. 1 and showing those of other embodiments.

FIGS. 4A to 4C are views showing a manufacturing process of the semiconductor laser according to the present invention and showing cross sections perpendicular to the resonance cavity end faces.

FIG. 5 is a view showing one surface of resonance cavity end faces of the semiconductor laser according to an embodiment of the present invention.

FIG. 6 is a perspective view explaining a conventional semiconductor laser.

### EXPLANATIONS OF LETTERS OR NUMERALS

1: substrate
4: active layer
5: metal layer portion
6: resonance cavity end face
9: semiconductor lamination portion

### THE BEST EMBODIMENT OF THE PRESENT INVENTION

A description will be given below of an embodiment of the present invention in reference to the drawings.

As shown in FIG. 1, a semiconductor laser according to the present invention includes a substrate 1 and a semiconductor lamination portion 9 formed on the substrate 1. The semiconductor lamination portion 9 including an active layer 4 is made of, for example, a nitride material having a cleavage plane not parallel to a cleavage plane of the substrate 1 and has resonance cavity end faces 6 from one of which a laser beam is mainly emitted. And a metal layer portion 5 is provided between the substrate 1 and the active layer 4 in a vicinity of the resonance cavity end faces 6.

The metal layer portion 5 is positioned between the substrate 1 and the active layer 4 in a vicinity of the resonance cavity end faces 6 and prevents a crack caused in the substrate 1 in a step of cleaving from reaching to the semiconductor lamination portion laminated on the substrate, more specifically to the active layer 4. Here, as the vicinity of the resonance cavity end faces 6 means a region containing at least an end face from which the laser beam is emitted, the case that the metal layer portion 5 is formed beyond the above described region is included in the present invention.

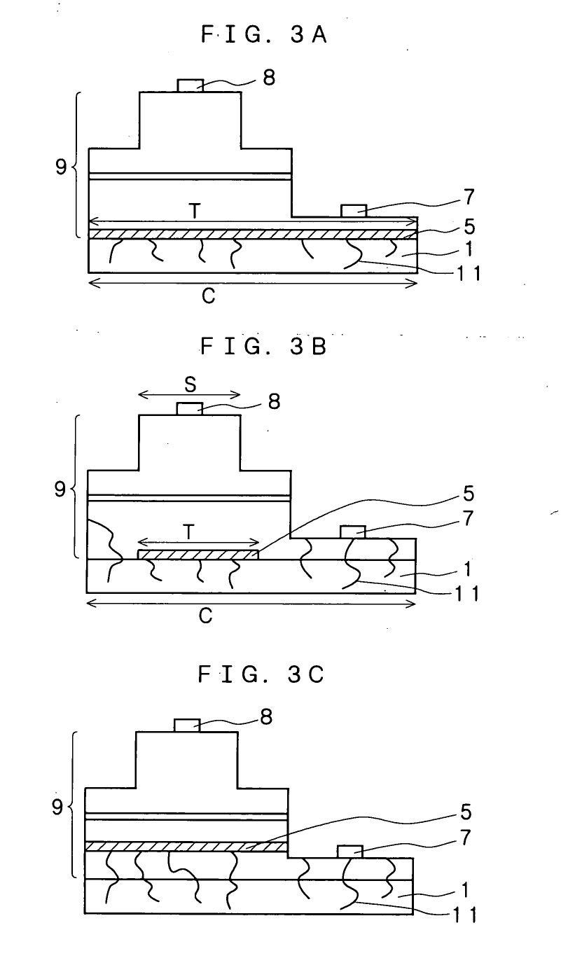

By inserting the metal layer portion 5, the substrate 1 and the active layer 4 are not contacted only through the semiconductor layer each other directly. Then, as shown in FIG. 3A showing a view of one surface of the resonance cavity end faces of the semiconductor laser shown in FIG. 1, when a cleavage plane of the semiconductor lamination portion 9 is used as the resonance cavity end faces 6, a crack 11 caused by a difference of a cleavage plane from that of the substrate does not extend to the semiconductor lamination portion 9 of the above by the existence of the metal layer portion 5. Thereby, any of the cracks 11 is not caused in the semiconductor lamination portion 9, the semiconductor lamination portion 9, more specially the active layer 4, can be mirror-finished and an absorption loss can be reduced at the resonance cavity end faces 6. And, because a more mirror-like surface than the artificially finished surface of the resonance cavity end faces by a method of dry etching or the like can be obtained, the absorption loss at the resonance cavity end faces is reduced and the semiconductor laser which is driven with low operating current and has high reliability can be obtained.

FIG. 3A shows a case that a width T of the metal layer portion 5 which is perpendicular to a direction of the resonance cavity of the semiconductor laser and to a direction of a laminating of the semiconductor lamination portion 9 is equal to a width c of a semiconductor laser chip, and on the other hand, FIG. 3B shows a case that the width T of the metal layer portion 5 is narrower than the width C of the semiconductor laser chip, but it is more preferable that the width T of the metal layer portion 5 is wider than a width S of a stripe of a mesa stripe-shaped portion which constricts a region of a current injection. Namely, if the crack 11 does not extend to a region of a high optical density of the active layer 4, the absorption loss at the resonance cavity end faces hardly occurs. As the region of the high optical density is as wide as the width S of the stripe-shaped portion, if the width T of the metal layer portion 5 is wider than the above described width S, the absorption loss is reduced inevitably.

And although, in examples shown in FIG. 1, FIG. 3A and FIG. 3B, the metal layer portion 5 is formed in a part of the semiconductor lamination portion 9 being contacted to the substrate, but it is not always necessary that the metal layer portion contacts to the substrate 1. For example, as shown in FIG. 3C, the metal layer portion 5 can be formed at any places up to the active layer 4.

It is preferable that the metal layer portion 5 includes an element which is contained in the semiconductor lamination portion 9. By this composition, the active layer 4 is not deteriorated in a crystal structure and the manufacturing process can be an easy one. Namely, in case of including the element being contained in the semiconductor lamination portion 9, the metal layer portion 5 can be formed by melting a part of the semiconductor lamination portion 9 after laminating the semiconductor lamination portion 9. Thereby, the semiconductor lamination portion 9 of fine quality can be kept without any influence to the crystal structure of the semiconductor lamination portion 9. And as described below, only by adding a process of melting a part of the semiconductor lamination portion 9 from a back surface of the substrate 1, the metal layer portion 5 including the element being contained in the semiconductor lamination portion 9 can be formed and any complication of the manufacturing process is not introduced. More concretely, in case that the semiconductor lamination portion 9 is made of an AlₓGa_{y}In_{1-x-y}N based compound material, Ga, Al, In or an alloy of these elements forms the metal layer portion 5, and in case of using other materials the same way of thinking is available. As described above, it is preferable to form the metal layer portion after forming the semiconductor lamination portion 9, but the way is not limited to this.

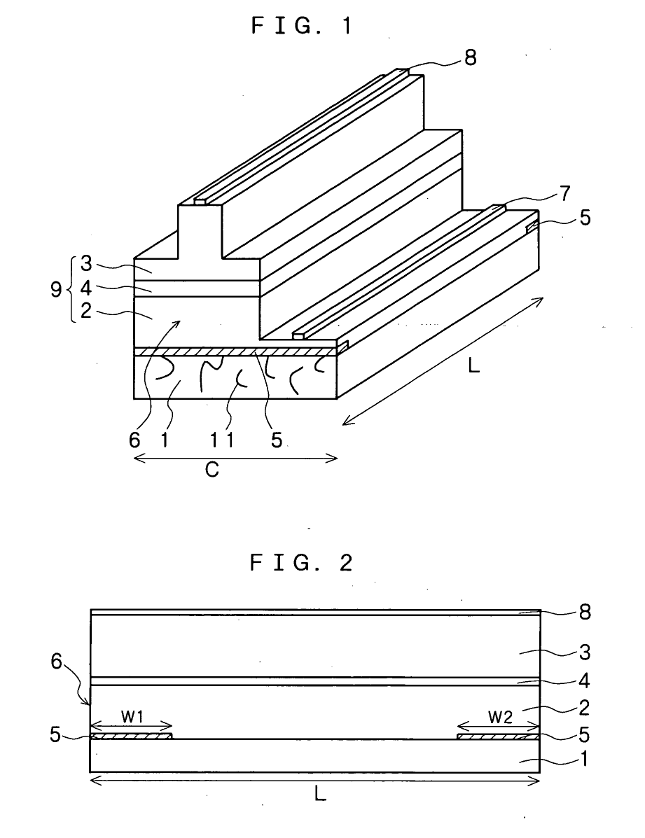

And as shown in FIG. 2 which is a cross-sectional view perpendicular to the resonance cavity end faces being shown in FIG. 1, the metal layer portion 5 is formed inside from the resonance cavity end face 6. Here, a length W (=W1+W2) which is a total of both lengths from the resonance cavity end faces 6 to metal layer ends inside the semiconductor laser is preferably smaller than a half of a length L of the resonance cavity. Because increasing of W makes a contact area of the substrate 1 and the semiconductor lamination portion 9 smaller at a border surface. And in case that W becomes larger than a half of the resonance cavity length L, the probability of peeling of the substrate in a packaging process increases rapidly. On the other hand, as described below, it is preferable that the length W (=W1+W2) is longer than an allowable distance of the deviation of the position of the cleaving, in order to form the metal layer portion 5 on the cleavage plane certainly.

For example, a sapphire substrate having a c-face (c-plane) as a principal plane is used for the substrate 1, but, not being limited to this, the sapphire substrate having other plane as the principal plane can be used. And, an insulating substrate, a p-type or an n-type substrate, a substrate of a material other than sapphire such as silicon carbide (SiC) or others can be used as the substrate 1. Though, as described below, materials which do not absorb a laser beam emitted from an irradiating laser 13 are preferable, because the laser beam is irradiated from a back surface by a YAG laser or the like.

The semiconductor lamination portion 9 is formed of a material having a cleavage plane not parallel to the cleavage plane of the substrate 1 on the substrate 1, and includes the active layer 4. Here, a material group to be used for the semiconductor lamination portion 9 has no limitation, but, in case of a nitride material, it arises occasionally that a cleavage plane is not parallel to that of the substrate 1. The nitride material means a material which is represented by a general formula AlₓGa_{y}In_{1-x-y}N (0≦x≦1, 0≦y≦1, 0≦x+y≦1). For example, in case that the resonance cavity end faces are formed by forming the semiconductor lamination portion 9 containing GaN by using a sapphire substrate having a principal plane of a crystal plane c, although a cleavage plane of GaN is a crystal plane M generally and the cleavage plane of the sapphire substrate of the crystal plane c is also the crystal plane M, but the both are not parallel to each other. And in case of using a sapphire substrate having a (0112) plane as the principal plane, the cleavage plane is an crystal plane R and is not parallel to the M-plane of the cleavage plane of GaN. Therefore, these cases described above are included in the present invention. Here, the material having a cleavage plane not parallel to that of the substrate includes all materials except materials having the cleavage plane parallel to that of the substrate, and in case that the substrate has no cleavage plane, it includes any material if the semiconductor lamination portion has the cleavage plane. That is, when the substrate just like having a breaking plane and actually having no cleavage plane is used, no matter what material is used for the semiconductor lamination portion 9, this case is included in the present invention. A double hetero structure, where a first conductivity type semiconductor layer 2 and a second conductivity type semiconductor layer 3 are formed to sandwich the active layer 4, is preferable to increase a light emitting efficiency.

It does not matter whether the active layer 4 is formed by a structure of a bulk, of a single quantum well, of an multi quantum well or of the like. In case of employing the structure of the quantum well, as a layer of a small band gap for a well layer and a layer of a large band gap for a barrier layer are used, then, for example, an InGaN layer or the like for the well layer and a GaN layer or the like for the barrier layer are used.

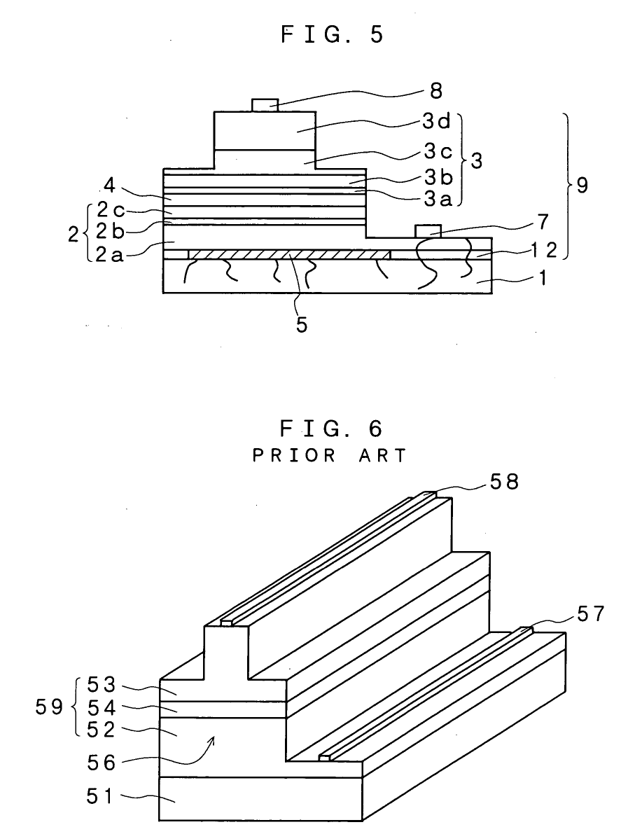

For the first conductivity type semiconductor layer 2, a layer of an n-type or a p-type, a single layer or a multi layer can be employed and a thickness of the layer is adjusted depending on a desired value respectively. In an embodiment shown in FIG. 5, although a three-layer structure containing an n-type GaN contact layer 2a, an n-type AlₓGa_{y}N clad layer 2b, and an n-type GaN guide layer 2c is applied, those layers are not always necessary and a single layer having both functions of the contact layer and the clad layer can be used. A layer of a super lattice is to be used and a layer having other function can be added.

And, between the first conductivity type semiconductor layer 2 and the substrate 1, a buffer layer 12 is formed. The buffer layer 12 has a function to alleviate a lattice mismatch between the substrate 1 and the first conductivity type semiconductor layer 2 and a material of AlₓGa_{y}In_{1-x-y} is preferable but it is not limited to this.

The second conductivity type semiconductor layer 3, which is reversely conductivity type to the first conductivity type semiconductor layer 2, in which a single layer or a multi layer can be employed and a thickness of the layer is adjusted depending on a desired value respectively. In the embodiment shown in FIG. 5, although a four-layer structure containing a p-type Al_{x′}Ga_{y′}N electronic barrier layer 3a, a p-type GaN guide layer 3b, a p-type Al_{x′}Ga_{y′}N clad layer 3c and a p-type GaN contact layer 3d, a single layer having both functions of the contact layer and the clad layer can be used. A layer of a super lattice is to be used and a layer having other function can be added. As the p-type semiconductor layer is usually non-active just after being laminated, it is preferable that the semiconductor layer of the p-type of the semiconductor lamination portion 9 is activated by annealing or the like. An annealing is processed with a protection layer being made of SiO₂ or Si₃N₄ covering whole surface of the second conductivity type semiconductor layer 4 or is processed without forming the protection layer. A condition of the annealing can be adjusted so as to get an effective activation properly. In addition, the activation with other method except the annealing is allowed or can be omitted when the activation is not necessary.

In forming the active layer 4, the first conductivity type semiconductor layer 2 and the second conductivity type semiconductor layer 3 described above, in order to get an n-type layer, in an MOCVD method, Se, Si, Ge or Te is mixed into a reaction gas in a form of an impurity source gas of H₂Se, SiH₄, GeH₄, TeH₄ or the like, and in order to get a p-type layer, Mg or Zn is mixed into a source gas in a form of an organic metal gas of EtCp₂Mg and DMZn. As the n-type layer is formed spontaneously without mixing impurities because N is easy to evaporate in a process of forming layers, therefore in case of forming the n-type layer, this property can be used.

And, as shown in the examples of FIGS. 1 to 3, a first electrode 7 is formed on a part of the first conductivity type semiconductor layer 2 being exposed, and a second electrode 8 is formed on a top-most surface of the second conductivity type semiconductor layer 3 being formed in a stripe shape. Mesa-etching to make the stripe shape and forming the exposed surface of the first conductivity type semiconductor layer 2, are processed by a method of dry etching or the like, for example a reactive ion etching with an atmosphere of a mixed gas of Cl₂ and BCl₃.

The first electrode 7 is electrically connected onto the exposed surface of the first conductivity type semiconductor layer 2, and the second electrode 8 is electrically connected onto the second conductivity type semiconductor layer 3. For example, in case of an n-type layer to be connected to an electrode, the electrode is made of Ti/Al, Ti/Au or the like, and in case of a p-type layer to be connected to an electrode, the electrode is made of Pd/Au, Ni/Au or the like, but they are not always limited to these. In one embodiment shown in FIG. 5, the first electrode 7 is made of Ti/Al and formed on the contact layer 2a being made of n-type GaN which is the exposed surface of the first conductivity type layer 2, and the second electrode 8 is made of Pd/Au and formed on the contact layer 3d being made of p-type GaN which is formed on the top-most surface of the second conductivity type layer 3.

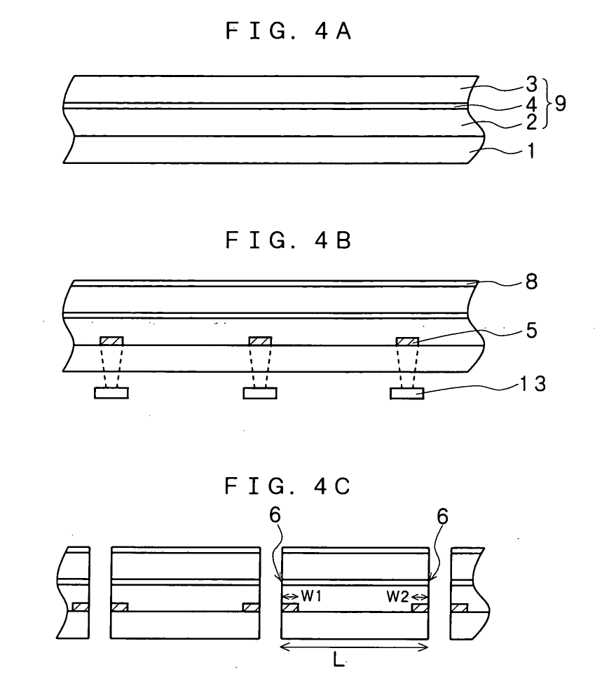

An explanation on a method of manufacturing according to the present invention will be given below in reference to FIGS. 4A to 4C. FIGS. 4A to 4C are cross-sectional views from a direction perpendicular to the resonance cavity end faces, for explaining the method according to the present invention. The method for manufacturing the semiconductor laser according to the present invention includes the steps of: forming the semiconductor lamination portion 9 including the active layer 4 on the substrate 1. The semiconductor lamination portion 9 is made of the material having the cleavage plane not parallel to the cleavage plane of the substrate 1. Thereafter, are followed the steps of forming the metal layer portion 5 by melting a part of the semiconductor lamination portion 9, and forming the resonance cavity end faces 6 by cleaving the semiconductor lamination portion 9 at the metal layer portion 5. Further, an overlapping explanation will be omitted here, as is same to the described above.

Concretely, as shown in FIG. 4A, the semiconductor lamination portion 9 including the active layer 4 is formed on the substrate 1, which is made of the material having the cleavage plane not parallel to the cleavage plane of the substrate 1. This semiconductor lamination portion is generally formed by using an MOCVD method or the like. However, an MBE method or other growing methods can be used too. And, after forming the semiconductor lamination portion 9, an annealing treatment, a stripe etching, a mesa-etching, an electrode forming, a back lapping of the substrate or the like are applied properly.

Thereafter, as shown in FIG. 4B, a part of the semiconductor lamination portion 9 located between the substrate 1 and the active layer 4, and located in the vicinity of cleaving is melted. An irradiating laser can be used for melting and a depth of a melting area is properly adjusted by controlling a laser power, an irradiating period or the like. In the example shown in FIG. 4B, a part of the semiconductor lamination portion 9 is melted by using an irradiating laser 13 like a YAG laser or an EXCIMER laser. In this case, it is preferable that the irradiating laser has an enough power to melt a part of the semiconductor lamination portion 9 and that it can irradiate the laser beam from the back surface of the substrate 1 in order to reduce a damage of the semiconductor lamination portion 9. Furthermore, the irradiating laser 13 preferably has a longer wavelength than a wave length corresponding to a band gap of the substrate 1, to avoid an absorption loss at the substrate. At the same time, it is preferable that a wavelength of the irradiation laser is shorter than a wave length corresponding to a band gap of a material composing a layer to be melted in the semiconductor lamination portion 9, thereby a desired part can be melted correctly. And more, if the wavelength of the irradiating laser is longer than a wave length corresponding to a band gap of the active layer, the active layer does not suffer from any influence.

For example, in case of melting a layer being made of GaN, a YAG laser or an excimer laser can be used, but in case of melting a layer being made of AlₓGa_{y}N, the YAG laser cannot be used because the YAG laser beam is not absorbed at the layer being made of AlₓGa_{y}N. Then, in this case, a laser like the excimer laser having a wavelength which is shorter than that corresponding to a band gap of AlₓGa_{y}N should be used. On the contrary, by employing a layer being made of GaN on the substrate side and by employing a layer being made of AlₓGa_{y}N on the active layer side, the metal layer portion can be obtained only on the substrate side without any influence to the active layer by using the YAG laser.

Thereafter, as shown in FIG. 4C, by cleaving at the position of the melted metal layer portion 5 with a method of laser scribing or diamond scribing, the resonance cavity end faces 6 from which a laser beam is emitted are formed. Here, a width W(=W1+W2) of the metal layer portion 5 is preferably smaller than a half of the length L of the resonance cavity. Because increasing of W makes a contact area of the substrate and the semiconductor lamination portion smaller at an interface. And in case that W becomes larger than a half of the resonance cavity length L, the probability of peeling of the substrate in a packaging process increases rapidly. On the other hand, if the width W(=W1+W2), as shown in FIG. 4C, is not longer than the allowable distance (about 10 μm) of the deviation of the position of the scribing in a scribing process, there occurs a case that the metal layer portion 5 cannot be formed certainly at the resonance cavity end faces 6 due to a scribing displacement. Then it is specifically preferable that the width W is longer than 10 μm and smaller than a half of the length L of the resonance cavity.

### EXAMPLE OF THE EMBODIMENT

FIG. 5 is a view showing a resonance cavity end face of a semiconductor laser manufactured with a following example. On a sapphire substrate 1, follow layers are laminated in order with using TMG, TMA, TMI and NH₃ as sources by an MOCVD method. First, a buffer layer 12 of a thickness of about 0.01 to 0.2 μm made of n-type GaN is laminated. Thereafter up to about 700 to 1200° C., the first conductivity type semiconductor layer 2 is formed, which includes a contact layer 2a of a thickness of about 0.01 to 10 μm made of n-type GaN, a clad layer 2b of a thickness of about 0.01 to 2 μm made of n-type AlₓGa_{y}N (for example, x=0.10 and x+y=1), and a guide layer 2c of a thickness of about 0.01 to 0.3 μm. And, the active layer 4 of a thickness of about 0.001 to 0.2 μm in total is formed including a well layer made of a non-doped or, n-type or p-type In_{1-y}Ga_{y}N (for example, y=0.9 and x=0) and a barrier layer made of GaN. And the second conductivity type semiconductor layer 3 is formed, which includes an electron barrier layer 3a of a thickness of about 0.01 to 0.3 μm made of p-type AlₓGa_{y}N (for example, x=0.20 and x+y=1), a guide layer 3b of a thickness of about 0.01 to 0.3 μm made of p-type GaN, a clad layer 3c of a thickness of about 0.01 to 2 μm made of p-type AlₓGa_{y}N (for example, x=0.10 and x+y=1), and a contact layer 3d of a thickness of about 0.05 to 2 μm made of p-type GaN.

Thereafter, an SiO₂ protection film is formed on the whole surface of the contact layer 3d and is annealed at a temperature of about 400 to 800° C. for about 20 to 60 minute. After completing annealing, a mask is formed with a resist film or the like, the second conductivity type semiconductor layer 3 is etched in a stripe shape until the clad layer 3c of p-type is exposed by the method of a reactive ion etching (dry etching) in an atmosphere of a mixed gas of Cl₂ and BCl₃. Thereafter, forming a mask on a stripe-shaped portion with a resist film or the like, the dry etching is applied again in order to get a mesa structure, until the n-type contact layer 2a is exposed. And, the second electrode 8 is formed on the p-type contact layer by forming a metal film made of Pd, Au or the like by a method of sputtering or evaporating, and the first electrode 7 is formed on the exposed n-type contact layer 2a, by depositing a metal film made of Ti, Al or the like by a method of sputtering or evaporating. Then a thickness of the substrate 1 is reduced by lapping a back surface of the substrate 1. Thereafter, the metal layer portion 5 made of Ga is formed by melting the buffer layer 12 made of GaN using a YAG laser from a back surface of the substrate 1. And the resonance cavity end faces 6 are formed by cleaving with a diamond scriber at the metal layer portion 5 formed by melting and a protection film not shown in the figure is formed on the resonance cavity end faces 6 by sputtering or the like. At last, by scribing along directions of a resonance cavity parallel to an emitting direction, a semiconductor laser chip is obtained.

Here, in the embodiment shown in FIG. 5, as a low-temperature buffer layer 12 made of GaN is melted by the YAG laser, and the metal layer potion 5 is formed by a metal Ga, an element constituting the low-temperature buffer layer, but the present invention is not limited to this structure as described above. For example, it can be allowed that the metal layer portion 5 is formed in a part of the contact layer 2a and that the metal layer portion 5 may be formed by melting any layer down from the active layer 4. In case that a layer to be melted is made of InGaN based compound or AlGaN based compound, not GaN, the metal layer portion 5 can be made of alloys of In and Ga or of Al and Ga besides Ga.

### INDUSTRIAL APPLICABILITY

The present invention provides a high performance semiconductor laser in case that the semiconductor lamination portion is made of a material having a cleavage plane not parallel to a cleavage plane of the substrate, as exhibited in a semiconductor laser of a short wavelength like a blue laser employing a nitride semiconductor. And the semiconductor laser according to the present invention can be used as a pick-up light source for a CD, a DVD, a DVD-ROM, a CD-R/RW or the like.

1. A semiconductor laser comprising:
a substrate;
a semiconductor lamination portion including an active layer laminated on the substrate, the semiconductor lamination portion being made of a material having a cleavage plane not parallel to a cleavage plane of the substrate; and
a metal layer portion provided between the substrate and the active layer in a vicinity of a resonance cavity end face.

2. The semiconductor laser according to claim 1, wherein the metal layer portion includes an element which is contained in the semiconductor lamination portion.

3. The semiconductor laser according to claim 1, wherein the metal layer portion is formed so as to have a width which is wider than that of a stripe-shaped portion for emitting and narrower than that of a semiconductor chip.

4. The semiconductor laser according to claim 1, wherein the metal layer portion is formed on a part of the semiconductor lamination portion contacted with the substrate.

5. A method for manufacturing a semiconductor laser comprising the steps of:
forming a semiconductor lamination portion including an active layer on a substrate, the semiconductor lamination portion being made of the material having a cleavage plane not parallel to a cleavage plane of the substrate,
forming a metal layer portion by melting a part of the semiconductor lamination portion; and
forming resonance cavity end faces by cleaving the semiconductor lamination portion at the metal layer portion.

6. The method for manufacturing the semiconductor laser according to claim 5, wherein the process of forming the metal layer portion is performed by irradiating a laser beam from a back surface of the substrate opposite to a surface laminated with the semiconductor lamination portion, and thereby melting a part of the semiconductor lamination portion.

7. The method for manufacturing the semiconductor laser according to claim ˜6, wherein a wavelength of the laser beam is set longer than a wavelength corresponding to a band gap of the active layer and shorter than a wavelength corresponding to a band gap of a semiconductor layer to be melted.
